(19) United States
(12) Patent Application Publication
(10) Pub. No.: US 2015/0325814 A1
(43) Pub. Date: Nov. 12, 2015

(54) DISPLAY PANEL, MANUFACTURE METHOD THEREOF, AND DISPLAY DEVICE

(71) Applicant: BOE Technology Group Co., Ltd., Beijing (CN)

(72) Inventors: Dongfang YANG, Beijing (CN); Lujiang HUANGFU, Beijing (CN)

(73) Assignee: BOE TECHNOLOGY GROUP CO., LTD., Beijing (CN)

(21) Appl. No.: 14/381,048

(22) PCT Filed: Dec. 10, 2013
(86) PCT No.: PCT/CN2013/089019

§ 371 Date: Aug. 26, 2014

(30) Foreign Application Priority Data
Sep. 11, 2013 (CN) 201310411215.8

(51) Int. Cl. H01L 51/52; H01L 51/50; H01L 51/56

(52) U.S. Cl. CPC H01L 51/5284; H01L 51/56; H01L 51/5012; H01L 51/5215; H01L 51/5234; H01L 51/5253

(57) ABSTRACT

A display panel comprising a substrate (10), an electroluminescent display structure (02) located at one side of the substrate (10), and an optically functional layer (21) configured for absorbing light located at one side of the electroluminescent display structure (02). The electroluminescent display structure (02) comprises a transparent first electrode layer (11), a transparent second electrode layer (13), and an organic luminescent layer (12) located between the first electrode layer (11) and the second electrode layer (13). The display panel can avoid any impact onto the display performance resulted by ambient light and improve the contrast ratio. A manufacture method of the display panel and a display device comprising the display panel are also disclosed.

### TECHNICAL FILED

Embodiments of the present invention relate to a display panel, a manufacture method thereof, and a display device.

### BACKGROUND

For existing display devices, an organic light emitting diode (OLED), as a current mode luminescent device, has been increasingly applied in the filed of high-performance display due to its characteristics such as self-luminescence, quick reactivity, broad visual angle and manufacturability on flexible substrate. Moreover, with the continuous development of display techniques, there are growing demands for the display performance of OLED displays.

Contrast ratio is one of the assessment parameters for display performance. With higher contrast ratio, the images as reproduced by a display device will present better layering, and the sharpness of the images will be increased, which leads to higher definition.

An existing OLED display is typically structured as shown in FIG. 1, comprising a substrate 10 as well as a first electrode layer 11, an organic luminescent layer 12 and a second electrode layer 13 which are disposed in sequence on a surface of the substrate 10. The OLED display supplies current to the organic luminescent layer 12 through the first electrode layer 11 and the second electrode layer 13, so that the current carriers in the organic luminescent layer 12 are injected into the organic luminescent materials, migrating, recombining and attenuating therein, thereby emitting light.

However, the first electrode layer 11 of the OLED display is usually made from a highly reflective and non-transparent metal. Thus the ambient light entering the OLED display through a display side surface thereof will be reflected by the surface of the first electrode layer 11 and the surface of the substrate 10. When the reflected ambient light 20 enters human eyes, they will disturb the display images received by the human eyes, thereby reducing the contrast ratio of the display, influencing the display effect and sacrificing the product quality.

### SUMMARY

Embodiments of the present invention provide a display panel, a manufacture method thereof, and a display device, which can avoid the influence on the display performance of the display resulted by the ambient light, increase the contrast ratio of the display device, and improve the display effect and product quality.

Embodiments of the present invention provide a display panel, comprising: a substrate; an electroluminescent display structure located at one side of the substrate, the electroluminescent display structure comprises a first electrode layer, a second electrode layer and an organic luminescent layer located between the first electrode layer and the second electrode layer, the first electrode layer is located at a side proximal to the substrate; and an optically functional layer configured for absorbing light located at one side of the electroluminescent display structure; wherein the first electrode layer and the second electrode layer both are transparent electrode layers.

Embodiments of the present invention, on another aspect, provide a display device comprising the above-mentioned display panel.

Embodiments of the present invention, on yet another aspect, provide a manufacture method of display panel, comprising: forming an optically functional layer configured for absorbing light on a surface of a substrate; forming a first electrode layer, an organic luminescent layer and a second electrode layer, in sequence, on the surface of the substrate where the optically functional layer is formed; the first electrode layer and the second electrode layer both are transparent electrode layers.

Embodiments of the present invention, on still another aspect, provide a manufacture method of display panel, comprising: forming a first electrode layer, an organic luminescent layer and a second electrode layer, in sequence, on a surface of a substrate; forming an optically functional layer configured for absorbing light on the surface of the substrate where the second electrode layer is formed; the first electrode layer and the second electrode layer both are transparent electrode layers.

Embodiments of the present invention provide a display panel, a manufacture method thereof and a display device, which can prevent the ambient light that enters a display device from being reflected by the display device and thus entering human eyes, which light may disturb the display images received by the human eyes and result in deterioration of display performance, thereby effectively increasing the contrast ratio of the display, and improving the display effect and product quality.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention; based on which, those skilled in the art can derive other drawings without any creative labors.

FIG. 1 is an existing structural schematic view illustrating a display panel;

FIG. 2 is a structural schematic view illustrating a display panel according to an embodiment of the present invention;

FIG. 3 is a structural schematic view illustrating an organic film layer according to an embodiment of the present invention;

FIG. 4 is a structural schematic view illustrating two types of display panels according to embodiments of the present invention;

FIG. 5 is a structural schematic view illustrating another type of display panel according to an embodiment of the present invention;

FIG. 6 is a structural schematic view illustrating yet another type of display panel according to an embodiment of the present invention.

### REFERENCE NUMERALS

02—electroluminescent display structure; 10—substrate; 11—first electrode layer; 12—organic luminescent layer; 121—organic luminescent material; 122—hole layer; 1221—hole injection layer; 1222—hole transmission layer; 123—electron layer; 1231—electron transmission layer; 1232—electron injection layer; 13—second electrode layer; 20—reflected ambient light; 21—optically functional layer; 22—optical coupling layer; 23—insulating layer.

### DETAILED DESCRIPTION OF THE PREFERRED EMBODIMENTS

In order to make objects, technical details and advantages of the embodiments of the invention apparent, technical solutions according to the embodiments of the present invention will be described clearly and completely as below in conjunction with the accompanying drawings of embodiments of the present invention. It is to be understood that the described embodiments are only a part of but not all of exemplary embodiments of the present invention. Based on the described embodiments of the present invention, various other embodiments can be obtained by those of ordinary skill in the art without creative labor and those embodiments shall fall into the protection scope of the present invention.

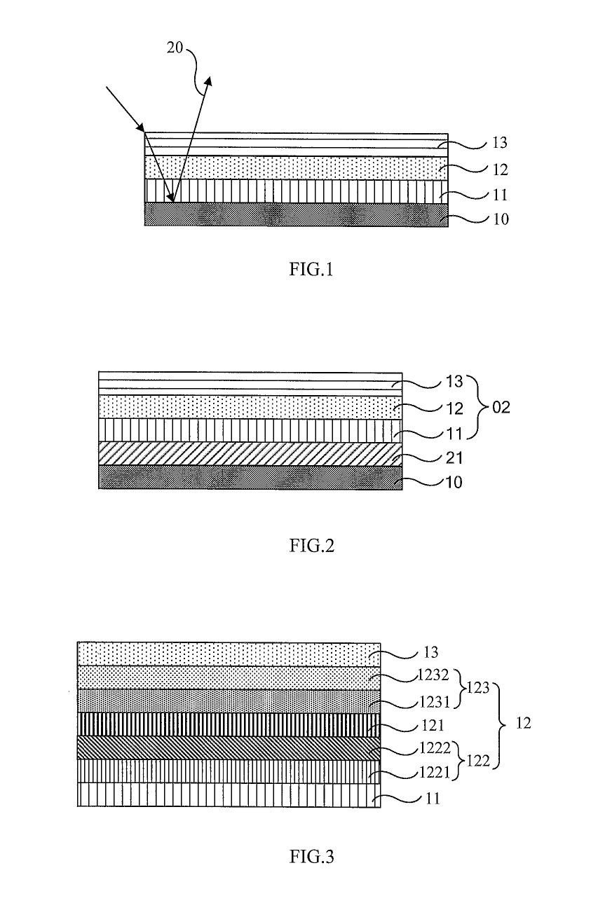

FIG. 2 shows a display panel according to an embodiment of the present invention, comprising a substrate 10 and an electroluminescent display structure 02 located at one side of the substrate 10; the electroluminescent display structure 02 comprises a first electrode layer 11, a second electrode layer 13, and an organic luminescent layer 12 located between the first electrode layer 11 and the second electrode layer 13; the first electrode layer 11 is located at a side proximal to the substrate 10.

It should be explained that, for a single-sided display, the substrate 10 can be made from a non-transparent material; in the case where the substrate 10 is made from transparent materials, the display panel can function for double-sided display.

It should be understood that the organic luminescent layer 12 will be described in details with reference to FIG. 3 by way of example. The organic luminescent layer 12 comprises an organic luminescent material 121; a hole layer 122 located between the organic luminescent material 121 and the first electrode layer 11; and an electron layer 123 located between the organic luminescent material 121 and the second electrode layer 13. The hole layer 122, in turn, comprises a hole injection layer 1221 located at a surface of the first electrode layer 11 and a hole transmission layer 1222 located at a surface of the hole injection layer 1221; the electron layer comprises an electron transmission layer 1231 located at a surface of the organic luminescent material 121 and an electron injection layer 1232 located at a surface of the electron transmission layer 1231. For such kind of OLED display device, when an electric filed is generated between the first electrode layer 11 and the second electrode 13, electrons and holes can be injected into the organic luminescent material 121 from the hole injection layer 1221 and the electron injection 1232, respectively, so as to migrate, recombine and attenuate within the organic luminescent material 121, thereby achieving display function of the OLED display.

Of course, the hierarchical structure of the organic luminescent layer 12 in OLED display is described herein by way of example only, without enumerating other organic luminescent layers having different hierarchical structures, which, however, shall fall within the protection scope of the present invention.

### First Embodiment

The display panel also comprises an optically functional layer 21 for absorbing light which is located at one side of the electroluminescent display structure 02.

It should be understood that, the optically functional layer 21 is transparent, and by absorbing the ambient light it reduces the impact onto the display images received by human eyes due to ambient light, thereby improving the contrast ratio of the display. The optically functional layer 21 can be made from an organic material such as at least one of titanium bronze (CuPc), buckminsterfullerene (C₆₀), TPCBI or buckminsterfullerene (C₇₀); or made from an inorganic material such as at least one of silicon aluminum oxide (SiO—Al) or aluminum oxide (Al₂O_{x<3}).

Herein, the first electrode layer 11 and the second electrode layer 13 both are transparent electrode layers.

The present embodiment provides a display panel comprising a substrate and an electroluminescent display structure located at one side of the substrate; the electroluminescent display structure comprises a transparent first electrode layer, a transparent second electrode layer, and an organic luminescent layer located between the first electrode layer and the second electrode layer; the first electrode layer is located at a side proximal to the substrate; furthermore, an optically functional layer capable of absorbing ambient light is disposed at one side of the electroluminescent display structure. In this way, it can prevent the ambient light that enters a display device from being reflected by the display device and thus entering human eyes which may disturb the display images received by the human eyes and result in deterioration of display performance. Therefore, such display panel can increase the contrast ratio of the display, and improve the display effect and product quality.

Hereinafter an example of the optically functional layer 21 for absorbing light that is disposed at one side of the electroluminescent display structure 02 will be described in details.

For example, as shown in FIG. 2, the optically functional layer 21 can be located between the substrate 10 and the first electrode layer 11. In this way, the optically functional layer 21 can not only absorb the ambient light that enters the OLED display through the display side surface and the side surfaces thereof, but also prevent the light from reaching the substrate 10 and being reflected there, so as to avoid the problem of disturbing the display images received by human eyes due to the reflected light which enters the human eyes. Furthermore, the electroluminescent display structure 02 emits light used for displaying images mostly through the display side of the display device, while the optically functional layer 21 disposed between the substrate 10 and the first electrode layer 11 is located at a surface away from the display side of the display device and thus will not significantly absorb the light which is used for displaying images and received by the human eyes. Therefore, it can increase the contrast ratio of the display, and improve the display effect and product quality, without impacting the transmissivity of the display device.

Alternatively, for another example, as shown in FIG. 4a, the optically functional layer 21 can be located at a display side of the electroluminescent display structure 02. In this way, the optically functional layer 21 can prevent the ambient light from entering the OLED display through the display side thereof and being reflected at the substrate 10, so as to prevent the reflected light from entering human eyes and disturbing the display images received by the human eyes, thereby avoiding any impact onto the contrast ratio of the display due to the ambient light, and improving the display effect and product quality.

Alternatively, for still another example, as shown in FIG. 4b, an optically functional layer 21 is disposed between the first electrode layer 11 and the substrate 10, and meanwhile another optically functional layer 21 is disposed on the surface of the second electrode layer 13. In this way, these two optically functional layers 21 can not only absorb the ambient light that enters the OLED display through the side surfaces thereof, but also absorb the ambient light that enters the OLED display through the display side thereof. Furthermore, since different visible light has different wavelengths, the light can be selectively absorbed by adjusting a thickness of the optically functional layer 21 located on the surface of the second electrode layer 13, without impacting the display effect of the display device. This extends the application filed of the display device.

The location arrangement of the optically functional layer 21 is described above by way of example only, without enumerating other hierarchical structures for the location arrangement of the optically functional layer 21, which, however, shall fall within the protection scope of the present invention.

### Second Embodiment

Further, in the case where the optically functional layer 21 is located at the display side of the electroluminescent display structure 02, as shown in FIG. 5, the display device of the present embodiment can also comprise an optical coupling layer 22 located between the second electrode layer 13 and the optically functional layer 21, for increasing the transmissivity of the display panel. It should be explained that, the optical coupling layer 22 is a substance layer capable of improving the refractive index of the light, thus can be made from a material with relatively larger refractive index, such as a material with a refractive index larger than 1.8; examples of such material include ZnO, ZnSe or the like. In this way, by additionally disposing an optical coupling layer 22 in the foregoing display device, the transmissivity of the OLED display panel can be increased, and the problem of deterioration in display effect resulted by the optically functional layer 21 absorbing part of emergent light of the display panel can be avoided.

### Third Embodiment

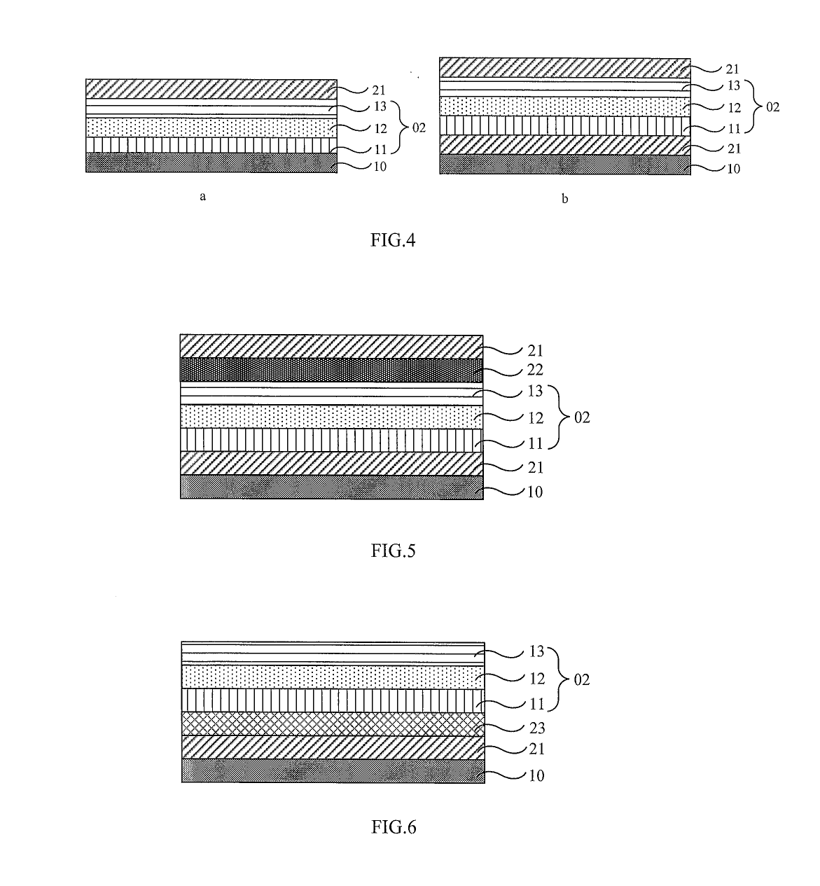

Further, in the case where the optically functional layer 21 is located between the substrate 10 and the first electrode layer 11, as shown in FIG. 6, the display device of the present embodiment can also comprise an insulating layer 23 located between the first electrode layer 11 and the optically functional layer 21. This insulating layer can be made from silicon nitride (SiNx) or silicon dioxide (SiO2). In this way, by additionally disposing an insulating layer 23 in the foregoing display device, any adverse effect to the first electrode layer resulted by the optically functional layer upon absorbing the ambient light can be avoided, so as to maintain the display effect of the display device without any impact.

Preferably, the optically functional layer 21 has an absorption spectral range from 380 nm to 780 nm because it needs to completely cover the absorption spectral range of the visible light which is from 380 to 780 nm. In this way, the optically functional layer 21 can absorb the ambient light, thereby increasing the contrast ratio and thus improving the display effect of the display.

It should be explained that, during the display operation of the OLED display, electrons and holes are injected into the organic luminescent materials in the organic luminescent layer 12 through both the first electrode layer 11 and the second electrode layer 13, respectively, under an externally applied electric filed, so as to migrate, recombine and attenuate within the organic luminescent materials and thus emit light, thereby achieving display function of the OLED display.

Herein, the first electrode layer 11 can be an anode and the second electrode layer 13 can be a cathode; or, the first electrode layer 11 can be a cathode and the second electrode layer 13 can be an anode. The present invention is not limited thereto.

Specifically, an embodiment of the present invention is described with reference to the case where the first electrode layer 11 is an anode and the second electrode layer 13 is a cathode, by way of example.

Embodiments of the present invention further provide a display device which comprises any one of the above-mentioned display panels and is beneficial in the same technical effects with that according to the foregoing embodiments of the present invention, thus no details thereof will be given due to the detailed explanations in terms of these display panels presented in the foregoing embodiments.

### Fourth Embodiment

The present embodiment provides a manufacture method of display panel, and as shown in FIG. 2, the method can be performed as below.

S101, forming an optically functional layer 21 for absorbing light on a surface of a substrate 10;

S102, forming a first electrode layer 11, an organic luminescent layer 12 and a second electrode layer 13, in sequence, on the surface of the substrate where the optically functional layer 21 is formed.

Herein, the first electrode layer and the second electrode layer both are transparent electrode layers. The first electrode layer 11 and the second electrode layer 13 can be made from a transparent conducting material such as indium tin oxide (ITO).

In this way, the optically functional layer 21 can not only absorb the ambient light that enters the OLED display from the display side surface thereof, but also prevent the light from reaching the substrate 10 and being reflected there.

It should be understood that by absorbing the ambient light the optically functional layer 21 reduces the impact onto the display images received by human eyes due to ambient light, thereby improving the contrast ratio of the display. The optically functional layer 21 can be made from an organic material such as at least one of titanium bronze (CuPc), buckminsterfullerene (C₆₀), TPCBI or buckminsterfullerene (C₇₀); or made from an inorganic material such as at least one of silicon aluminum oxide (SiO—Al) or aluminum oxide (Al₂O_{x<3}).

Further, as shown in FIG. 6, after forming the optically functional layer 21 for absorbing light on the surface of the substrate 10, the manufacture method can further comprise forming an insulating layer 23 on a surface of the optically functional layer 21. By means of the insulating layer, any adverse effect to the first electrode layer resulted by the optically functional layer upon absorbing the ambient light can be avoided, so as to maintain the display effect of the display device without any impact.

Preferably, the optically functional layer 21 has an absorption spectral range from 380 nm to 780 nm because it needs to completely cover the absorption spectral range of the visible light which is from 380 nm to 780 nm. In this way, the optically functional layer can absorb the ambient light, thereby increasing the contrast ratio and thus improving the display effect of the display.

It should be understood that, during the display operation of the OLED display, electrons and holes are injected into the organic luminescent materials in the organic luminescent layer 12 through both the first electrode layer 11 and the second electrode layer 13, respectively, under an externally applied electric filed, so as to migrate, recombine and attenuate within the organic luminescent materials and thus emit light, thereby achieving display function of the OLED display.

Herein, the first electrode layer 11 can be an anode and the second electrode layer 13 can be a cathode; or, the first electrode layer 11 can be a cathode and the second electrode layer 13 can be an anode.

The present embodiment further provides another manufacture method of a display panel, and as shown in FIG. 4a the method can be performed as below.

S201, forming a first electrode layer 11, an organic luminescent layer 12 and a second electrode layer 13, in sequence, on a surface of a substrate 10;

S202, forming an optically functional layer 21 for absorbing light on the surface of the substrate where the second electrode layer 13 is formed.

Herein, the first electrode layer 11 and the second electrode layer 13 both are transparent electrode layers. The first electrode layer 11 and the second electrode layer 13 can be made from a transparent conducting material such as indium tin oxide (ITO). In this way, it can prevent the ambient light from entering the OLED display through the display side thereof, so as to avoid any impact onto the contrast ratio of the display resulted by the ambient light.

It should be understood that, by absorbing the ambient light the optically functional layer 21 mitigates the impact to the display images received by the human eyes due to ambient light, so as to increase the contrast ratio of the display. The optically functional layer can be made from an organic material such as at least one of titanium bronze (CuPc), buckminsterfullerene (C₆₀), TPCBI or buckminsterfullerene (C₇₀); or made from an inorganic material such as at least one of silicon aluminum oxide (SiO—Al) and aluminum oxide (Al₂O_{x<3}).

Further, as shown in FIG. 5, before forming the optically functional layer 21 for absorbing light on the surface of the substrate 10 which has been formed with the structure above, the manufacture method can also comprise forming an optical coupling layer 22 for increasing the transmissivity of the display panel on the surface of the substrate where the second electrode layer 13 is formed. In this way, by means of the optical coupling layer 22, the transmissivity of the OLED display panel can be increased, and the deterioration in display effect resulted by the optically functional layer 21 through absorbing part of emergent light of the display panel can be avoided.

Preferably, the optically functional layer 21 has an absorption spectral range from 380 nm to 780 nm because it needs to completely cover the absorption spectral range of the visible light which is from 380 nm to 780 nm. In this way, the optically functional layer can absorb the ambient light, thereby increasing the contrast ratio and thus improving the display effect of the display.

Further, the first electrode layer 11 can be an anode and the second electrode layer 13 can be a cathode; or, the first electrode layer 11 can be a cathode and the second electrode layer 13 can be an anode.

Embodiments of the present invention provide a manufacture method of display panel. The display panel comprises a substrate and an electroluminescent display structure located at one side of the substrate; the electroluminescent display structure comprises a transparent first electrode layer, a transparent second electrode layer, and an organic luminescent layer located between the first electrode layer and the second electrode layer; the first electrode layer is located at a side proximal to the substrate; an optically functional layer capable of absorbing light is disposed at one side of the electroluminescent display structure. In this way, it can prevent the ambient light that enter a display device from being reflected by the display device and thus entering human eyes which may disturb the display images received by the human eyes and result in deterioration of display performance, thereby increasing the contrast ratio of the display, and improving the display effect and product quality.

The invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

1. A display panel, comprising:
a substrate;
an electroluminescent display structure located at one side of the substrate, wherein the electroluminescent display structure comprises a first electrode layer, a second electrode layer, and an organic luminescent layer located between the first electrode layer and the second electrode layer, and the first electrode layer is located at a side proximal to the substrate; and
an optically functional layer configured for absorbing light, located at one side of the electroluminescent display structure;
wherein the first electrode layer and the second electrode layer both are transparent electrode layers.

2. The display panel according to claim 1, wherein the optically functional layer is located between the substrate and the first electrode layer; or, the optically functional layer is located at a display side of the electroluminescent display structure.

3. The display panel according to claim 2, wherein the optically functional layer is located at the display side of the electroluminescent display structure, and the display panel further comprises:
an optical coupling layer configured for increasing a transmissivity of the display panel, located between the second electrode layer and the optically functional layer.

4. The display panel according to claim 2, wherein the optically functional layer is located between the substrate and the first electrode layer, and the display panel further comprises:
an insulating layer located between the first electrode layer and the optically functional layer.

5. The display panel according to claim 1, wherein the optically functional layer has an absorption spectral range from 380 nm to 780 nm.

6. The display panel according to claim 1, wherein
the first electrode layer is an anode and the second electrode layer is a cathode; or,
the first electrode layer is a cathode and the second electrode layer is an anode.

7. A display device, comprising a display panel according to claim 1.

8. A manufacture method of display panel, comprising:
forming an optically functional layer configured for absorbing light on a surface of a substrate; and
forming a first electrode layer, an organic luminescent layer and a second electrode layer, in sequence, on the surface of the substrate where the optically functional layer is formed;
wherein the first electrode layer and the second electrode layer both are transparent electrode layers.

9. The manufacture method according to claim 8, wherein after forming the optically functional layer configured for absorbing light on the surface of the substrate, the manufacture method further comprises:
forming an insulating layer on the optically functional layer.

10. The manufacture method according to claim 8, wherein the optically functional layer has an absorption spectral range from 380 nm to 780 nm.

11. The manufacture method according to claim 8, wherein
the first electrode layer is an anode and the second electrode layer is a cathode; or,
the first electrode layer is a cathode and the second electrode layer is an anode.

12. A manufacture method of display panel, comprising:
forming a first electrode layer, an organic luminescent layer and a second electrode layer, in sequence, on a surface of a substrate; and
forming an optically functional layer configured for absorbing light on the surface of the substrate where the second electrode layer is formed;
wherein the first electrode layer and the second electrode layer both are transparent electrode layers.

13. The manufacture method according to claim 12, wherein before forming the optically functional layer configured for absorbing light on the surface of the substrate which has been formed with the structure above, the manufacture method further comprises:
forming an optical coupling layer for increasing a transmissivity of the display panel on the surface of the substrate where the second electrode layer is formed.

14. The manufacture method according to claim 12, wherein the optically functional layer has an absorption spectral range from 380 nm to 780 nm.

15. The manufacture method according to claim 12, wherein
the first electrode layer is an anode and the second electrode layer is a cathode; or,
the first electrode layer is a cathode and the second electrode layer is an anode.

16. The manufacture method according to claim 13, wherein the optically functional layer has an absorption spectral range from 380 nm to 780 nm.

17. The manufacture method according to claim 13, wherein
the first electrode layer is an anode and the second electrode layer is a cathode; or,
the first electrode layer is a cathode and the second electrode layer is an anode.

18. The manufacture method according to claim 14, wherein
the first electrode layer is an anode and the second electrode layer is a cathode; or,
the first electrode layer is a cathode and the second electrode layer is an anode.

19. The display panel according to claim 3, wherein the optically functional layer has an absorption spectral range from 380 nm to 780 nm.

20. The display panel according to claim 3, wherein
the first electrode layer is an anode and the second electrode layer is a cathode; or,
the first electrode layer is a cathode and the second electrode layer is an anode.
